(19) United States
(12) Patent Application Publication
(10) Pub. No.: US 2026/0311973 A1
(43) Pub. Date: Oct. 8, 2026

(54) METHOD OF FORMING PROTECTIVE FILM ON OUTER CIRCUMFERENTIAL PORTION INCLUDING BEVEL PORTION OF SUBSTRATE

(71) Applicants: EBARA CORPORATION, Tokyo (JP); NATIONAL UNIVERSITY CORPORATION TOKAI NATIONAL HIGHER EDUCATION AND RESEARCH SYSTEM, Aichi (JP)

(72) Inventors: Jumpei FUJIKATA, Tokyo (JP); Tetsuji TOGAWA, Tokyo (JP); Masahiro HATAKEYAMA, Tokyo (JP); Kazuhito TSUJI, Tokyo (JP); Masaru HORI, Aichi (JP); Naoto MIYASHITA, Aichi (JP); Makoto SEKINE, Aichi (JP)

(21) Appl. No.: 19/483,950

(22) PCT Filed: Mar. 18, 2024
(86) PCT No.: PCT/JP2024/010493

§ 371 Date: Nov. 12, 2025

(30) Foreign Application Priority Data
Jun. 1, 2023 (JP) 2023-090817

(51) Int. Cl. H01J 37/32; C23C 16/27; C23C 16/455; C23C 16/50; H10P 14/43; H10P 14/60; H10P 14/69

(52) U.S. Cl. CPC H01J 37/32568; C23C 16/27; C23C 16/45591; C23C 16/50; H01J 37/3244; H01J 37/32541; H10P 14/432; H10P 14/6336; H01J 2237/3321; H10P 14/6902

(57) ABSTRACT

An object is to improve the quality of a protective film provided to protect an outer circumferential portion of a substrate. There is provided a method of forming a protective film on an outer circumferential portion including a bevel portion of a substrate by using a plasma. The method comprises: placing the substrate having a first face and a second face that are opposed to each other, on a stage having smaller dimensions than dimensions of the substrate, such as to bring the second face of the substrate into contact with the stage and to cause the outer circumferential portion of the substrate to be protruded from an outer edge of the stage; causing at least part in a circumferential direction of the outer circumferential portion of the substrate to be opposed to an electrode; causing a first shielding structure that separates the outer circumferential portion of the substrate from an inner side area on an inner side of the outer circumferential portion of the substrate to come into contact with the first face of the substrate, and/or, causing a second shielding structure that separates the outer circumferential portion of the substrate from the inner side area of the substrate to come into contact with the second face of the substrate; and supplying a film-forming gas to between the outer circumferential portion of the substrate and the electrode, so as to form a protective film on the outer circumferential portion of the substrate.

### TECHNICAL FIELD

The present disclosure relates to a method of processing a substrate or more specifically a method of forming a protective film on an outer circumferential portion including a bevel portion of a substrate.

### BACKGROUND ART

As described in Japanese U.S. Pat. No. 3,949,941 (PTL 1), in a semiconductor manufacturing process, an outer circumferential portion (an edge portion and a bevel portion) of a substrate may be corroded at the time of an etching process of the substrate. This is likely to cause the outer circumferential portion of the substrate to be damaged during delivery of the substrate or during processing of the substrate. Furthermore, particles may be trapped in a corroded part. The trapped particles are likely to adversely affect the subsequent processing of the substrate and is, as a result, likely to lower the yield.

Japanese U.S. Pat. No. 5,982,383 (PTL 2) has proposed a method of forming a protective film on the outer circumferential portion (the edge portion and the bevel portion) of the substrate to protect the outer circumferential portion from etching, as a solution to the above problem. This technique causes plasma to be kept in only the outer circumferential portion of the substrate, while regulating an electrode gap in a center portion of the substrate to a predetermined distance such as to provide a pressure for preventing formation of the plasma, with a view to forming a protective film only on the outer circumferential portion of the substrate. Japanese Unexamined Patent Publication No. 2020-021931 (PTL 3) has proposed a configuration of placing an electrode only to part of the outer circumferential portion of the substrate and rotating the substrate to make the outer circumferential portion of the substrate subjected to plasma processing. Any of the techniques disclosed in these patent literatures causes a gas to flow in from the center portion of the substrate and places the electrode in the outer circumferential portion of the substrate.

### CITATION LIST

### Patent Literature

PTL 1: Japanese U.S. Pat. No. 3,949,941

PTL 2: Japanese U.S. Pat. No. 5,982,383

PTL 3: Japanese Unexamined Patent Publication No. 2020-021931

### SUMMARY OF INVENTION

### Technical Problem

The methods described above, however, cause the boundary of the gas pressure to be varied continuously and thereby have an unclear boundary between a space where plasma is kept and a space where formation of plasma is prevented. In the case where a protective film is formed on the outer circumferential portion of the substrate by plasma processing, this results in incomplete film formation on an inner boundary of the protective film. This is likely to decrease the film thickness on the inner boundary of the protective film or is likely to reduce the adhesiveness of the protective film. As a result, this may cause peel-off of the protective film and generation of particles in a process subsequent to formation of the protective film.

There may be a method of improving the uniformity in the film thickness on the boundary by forming a protective film on the outer circumferential portion of the substrate after formation of a resist film in a remaining portion other than the outer circumferential portion of the substrate and subsequently removing the resist film. This method is, however, expected to require a large cost for a resist application step, a basking step and a removal step.

One object of the present disclosure is to solve at least part of the problems described above. One object of the present disclosure is to improve the quality of a protective film provided to protect an outer circumferential portion of a substrate.

### Solution to Problem

There is provided a method of forming a protective film on an outer circumferential portion including a bevel portion of a substrate by using a plasma. The method comprises: placing the substrate having a first face and a second face that are opposed to each other, on a stage having smaller dimensions than dimensions of the substrate, such as to bring the second face of the substrate into contact with the stage and to cause the outer circumferential portion of the substrate to be protruded from an outer edge of the stage; causing at least part in a circumferential direction of the outer circumferential portion of the substrate to be opposed to an electrode; causing a first shielding structure that separates the outer circumferential portion of the substrate from an inner side area on an inner side of the outer circumferential portion of the substrate to come into contact with the first face of the substrate, and/or, causing a second shielding structure that separates the outer circumferential portion of the substrate from the inner side area of the substrate to come into contact with the second face of the substrate; and supplying a film-forming gas to between the outer circumferential portion of the substrate and the electrode, so as to form a protective film on the outer circumferential portion of the substrate.

### BRIEF DESCRIPTION OF DRAWINGS

FIG. 1 is a schematic diagram illustrating a configuration example of a substrate processing apparatus according to one embodiment;

FIG. 2 is a schematic diagram illustrating one configuration example of the substrate processing apparatus according to one embodiment;

FIG. 3A is a sectional view illustrating a configuration example of supplying a film-forming gas;

FIG. 3B is a bottom view illustrating a top cover;

FIG. 4A is a sectional view illustrating a configuration example of supplying the film-forming gas;

FIG. 4B is a bottom view illustrating a top cover;

FIG. 5 is a sectional view illustrating a configuration example of supplying the film-forming gas;

FIG. 6 is a sectional view illustrating a configuration example of supplying the film-forming gas;

FIG. 7A is a sectional view illustrating a configuration example of an electrode;

FIG. 7B is a plan view illustrating the configuration example of the electrode;

FIG. 8A is a sectional view illustrating a configuration example of a vertically split electrode in an open position;

FIG. 8B is a sectional view illustrating a configuration example of the vertically split electrode in a closed position;

FIG. 9A is a schematic diagram illustrating a connection example of connecting a substrate with a negative bias;

FIG. 9B is a schematic diagram illustrating a connection example of connecting a substrate with a negative bias;

FIG. 10A is a schematic diagram illustrating a connection example of biasing a top cover and a bottom cover;

FIG. 10B is a schematic diagram illustrating a connection example of biasing the top cover and the bottom cover;

FIG. 11A is an explanatory diagram illustrating a method of centering a substrate;

FIG. 11B is an explanatory diagram illustrating the method of centering the substrate;

FIG. 12A is an explanatory diagram schematically illustrating formation of a protective film according to one embodiment;

FIG. 12B is an explanatory diagram schematically illustrating formation of a protective film according to a comparative example;

FIG. 13A is a schematic diagram illustrating a substrate with a protective film formed thereon (a substrate with protective film) according to one example;

FIG. 13B is a schematic diagram illustrating a substrate with a protective film formed thereon (a substrate with protective film) according to one example;

FIG. 13C is a schematic diagram illustrating a substrate with a protective film formed thereon (a substrate with protective film) according to one example;

FIG. 13D is a schematic diagram illustrating a substrate with a protective film formed thereon (a substrate with protective film) according to one example;

FIG. 13E is a schematic diagram illustrating a substrate with a protective film formed thereon (a substrate with protective film) according to one example;

FIG. 14A is a flowchart showing a semiconductor manufacturing process;

FIG. 14B is flowchart showing a semiconductor manufacturing process;

FIG. 15A is flowchart showing a semiconductor manufacturing process; and

FIG. 15B is flowchart showing a semiconductor manufacturing process.

### DESCRIPTION OF EMBODIMENTS

The following describes one embodiment of the present disclosure with reference to the drawings. In the respective embodiments described below, identical or equivalent members are expressed by identical reference signs with omission of duplicated description. In the description hereof, the expressions such as “upper” or “upward”, “lower” or “downward”, “left” or “leftward” and “right” and “rightward” are used. These expressions indicate the positions, the orientations, and the directions on the sheet surface of the illustrated drawings for the purpose of explanation, and these positions, orientations and directions may be different from those in the actual arrangement, for example, when using the apparatus.

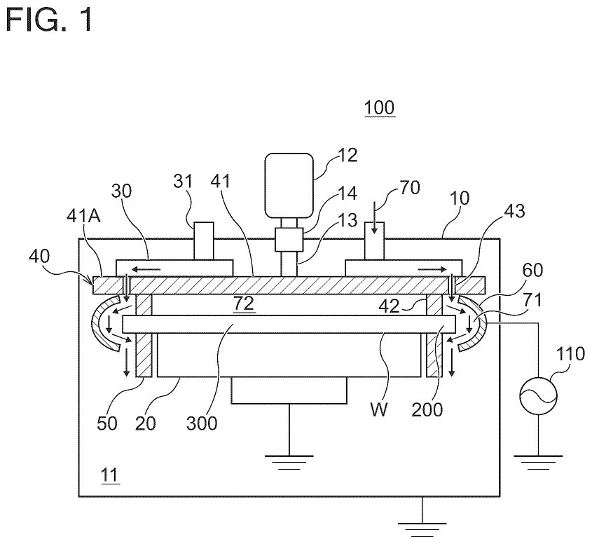

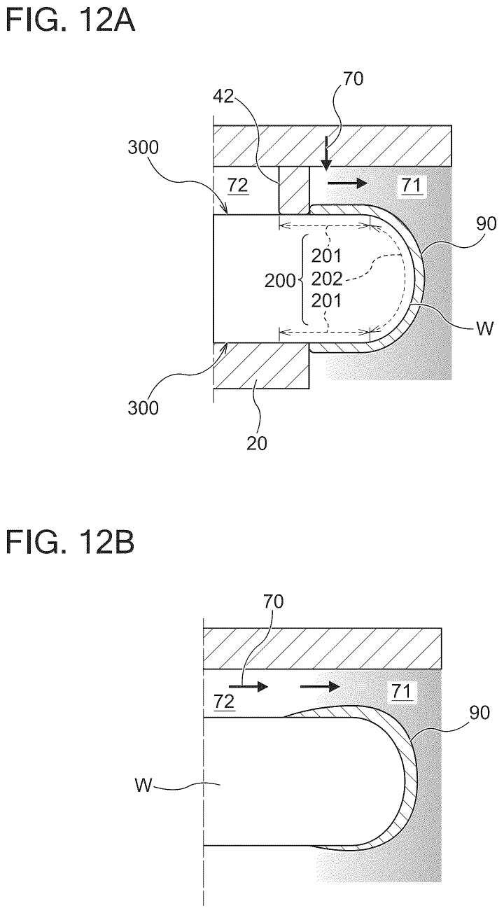

FIG. 1 is a schematic diagram illustrating a configuration example of a substrate processing apparatus 100 according to one embodiment. This substrate processing apparatus 100 is an apparatus configured to form a protective film 90 (shown in FIG. 12A) on an outer circumferential portion (an edge portion and a bevel portion) of a substrate W by local plasma. The substrate processing apparatus 100 may be a substrate processing apparatus using capacitively coupled plasma, inductively coupled plasma, microwave plasma or another plasma. According to the embodiment, a plasma film forming apparatus is described as an example of the substrate processing apparatus 100. The substrate processing apparatus 100 may, however, be a plasma etching apparatus or another plasma substrate processing apparatus. In the description hereof, as shown in FIG. 12A, an outer circumferential portion 200 of the substrate W includes an edge portion 201 and a bevel portion 202. The bevel portion 202 is a chamfered side face portion of the substrate W, and the edge portion 201 is a flat portion on an inner side of the bevel portion 202 in the outer circumferential portion 200 of the substrate W. According to the embodiment, an area (range) on an inner side of the outer circumferential portion 200 of the substrate W is called a center portion 300. According to the embodiment, out of a front face and a rear face of the substrate W (an upper face and a lower face in FIG. 1), the center portion 300 on the front surface serves as a device formation area. According to another embodiment, device formation areas may be provided on both the front surface and the rear face of the substrate W. The outer circumferential portion 200 may thus be defined as an area on an outer side of the device formation area. For example, when the device formation area is provided on the front surface of the substrate W, an area on the front surface and the rear face of the substrate W corresponding to the device formation area may be called the center portion 300, and an outer side of the center portion 300 on the front surface and the rear face of the substrate W may be called the outer circumferential portion 200.

According to the embodiment, the substrate W is, for example, a circular wafer with semiconductor devices, optical elements, MEMS and the like formed thereon. The substrate W may, however, be a substrate with other types of devices formed thereon. The substrate W may be a substrate in a polygonal shape (such as a rectangular shape) or in any arbitrary shape other than the circular shape. The substrate W may be a silicon substrate (including a substrate made of silicon as a material and a composite substrate such as an SOI substrate having a silicon surface), a compound semiconductor substrate or a substrate made of any other arbitrary material.

According to the embodiment, the protective film 90 may be an insulating film, a dielectric film, a conductor film, an organic film or any other film used in semiconductor production. The protective film 90 is preferably a film having etching resistance and high hardness. For example, an amorphous carbon film or a DLC (diamond-like carbon) film may be employed as the protective film 90.

The substrate processing apparatus 100 mainly includes a casing 10 that configures a plasma chamber 11, and a stage 20, an electrode 60, a top cover 40 and a bottom cover 50 placed inside of the casing 10.

The stage 20 includes a mounting surface which the substrate W is placed on, and has a chuck mechanism configured to fix the substrate W. The stage 20 may further have a heater function configured to heat the substrate W. This stage 20 is rotatable by a non-illustrated driving device, such as a motor. The substrate W as an object for formation of the protective film 90 is placed on the mounting surface (an upper face in FIG. 1) of the stage 20. The substrate W has a diameter that is larger than a diameter of the mounting surface of the stage 20. In other words, the diameter of the mounting surface of the stage 200 is smaller than the diameter of the substrate W. Accordingly, the outer circumferential portion 200 (the edge portion 201 and the bevel portion 202) of the substrate W is not supported by the stage 20. In this illustrated example, the stage 20 is connected with a ground potential, and the substrate W is connected with the ground potential via the stage 20. The casing 10 is also connected with the ground potential, and the stage 20 is connected with the ground potential via the casing 10.

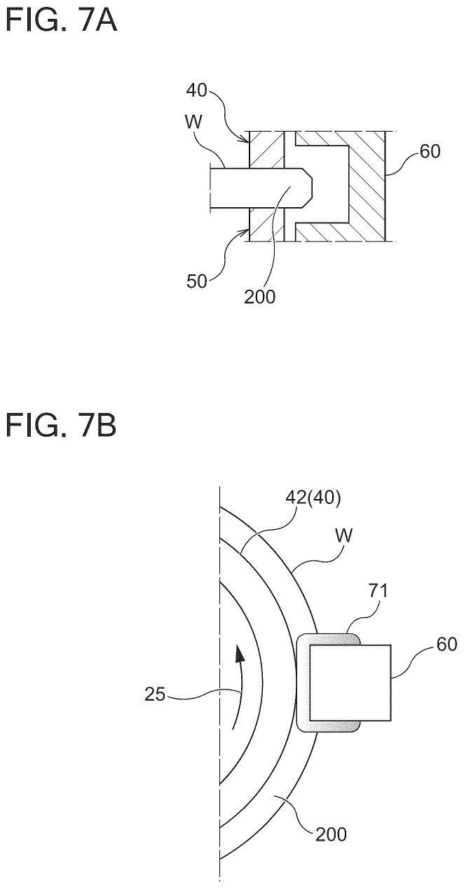

The electrode 60 is placed on an outer side of the stage 20 to be opposed to the outer circumferential portion 200 of the substrate W and has such a shape that laterally covers the outer circumferential portion 200 of the substrate W. For example, the electrode 60 has an arc-like sectional shape. The electrode 60 is made of an electrically conductive material, for example, a metal. The electrode 60 is connected with, for example, an RF power source 110 configured to supply a high-frequency power to the electrode 60. According to the embodiment, the high-frequency power is supplied from the electrode 60 to a film-forming gas 70, so as to ionize the film-forming gas 70 and generate plasma. According to another embodiment, the electrode 60 may be connected with a DC power source, and a DC power may be supplied from the electrode 60 to the film-forming gas 70, so as to ionize the film-forming gas 70 and generate the plasma. The electrode 60 is placed, such that a distance between the electrode 60 and the outer circumferential portion 200 (the edge portion 201 and the bevel portion 202) of the substrate W is fixed in a film-forming area or a plasma generation area 71. This configuration uniformizes the flow of the film-forming gas 70 flowing between the electrode 60 and the outer circumferential portion 200 of the substrate W. The plasma generation area 71 is a three-dimensional space and is also called plasma generation space. For example, the electrode 60 is provided continuously or intermittently (discretely) around the whole circumference of the substrate W as shown in FIG. 1. In another example, the electrode 60 may be placed in part of a circumferential direction of the substrate W as shown in FIG. 7B.

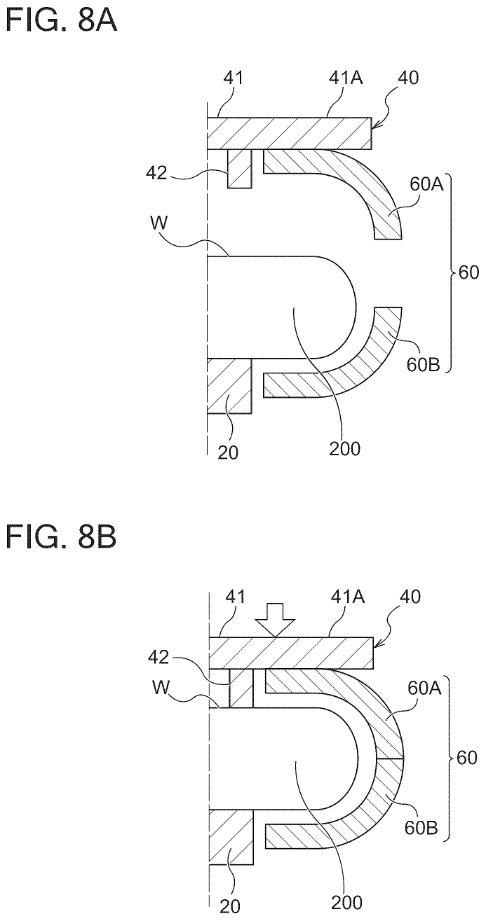

In the case where the electrode 60 is provided continuously around the whole circumference of the substrate W, it is preferable, for example, to vertically divide the electrode 60 into an upper electrode 60A and a lower electrode 60B as shown in FIG. 8A and FIG. 8B and thereby facilitate mounting and demounting of the substrate W. In the case where the electrode 60 is provided discretely around the whole circumference of the substrate W, it is preferable, for example, to move a plurality of individual electrodes 60 along a substrate diameter direction such as to be closer to and farther from the substrate W by means of a non-illustrated actuator and thereby facilitate mounting and demounting of the substrate W. In the case where the electrode 60 is placed in part of the circumferential direction of the substrate W, for example, the substrate W is rotated, so that the electrode 60 is sequentially opposed to the whole circumference of the substrate W and that the protective film 90 is formed along the whole circumference of the substrate W (as shown in FIG. 7B). In the case where the electrode 60 is placed in part of the circumferential direction of the substrate W, the electrode may be moved along the substrate diameter direction such as to be closer to and farther from the substrate W by means of a non-illustrated actuator. This configuration facilitates mounting and demounting of the substrate W.

The top cover 40 is a shielding structure configured to shield the center portion 300 (the area on the inner side of the outer circumferential portion 200) of the substrate W from the plasma. The top cover 40 has a hollow portion inside thereof. The center portion 300 of the substrate W (the center portion 300 on the upper face of the substrate W in FIG. 1) is placed in this hollow portion. The hollow portion inside of the top cover 40 and the center portion 300 of the substrate W form a plasma non-generation area 72 that is shielded from the plasma. The center portion 300 on the upper face of the substrate W forms the device formation area. The top cover 40 is placed such as not to directly come into contact with the device formation area. The internal pressure of the hollow portion of the top cover 40 may be lower than, higher than or equal to the vacuum pressure in the periphery of the outer circumferential portion 200 of the substrate W and may be, for example, the atmospheric pressure. The top over 40 may be made of a material having plasma resistance, for example, a polyimide, a metal coated with yttria, or another material.

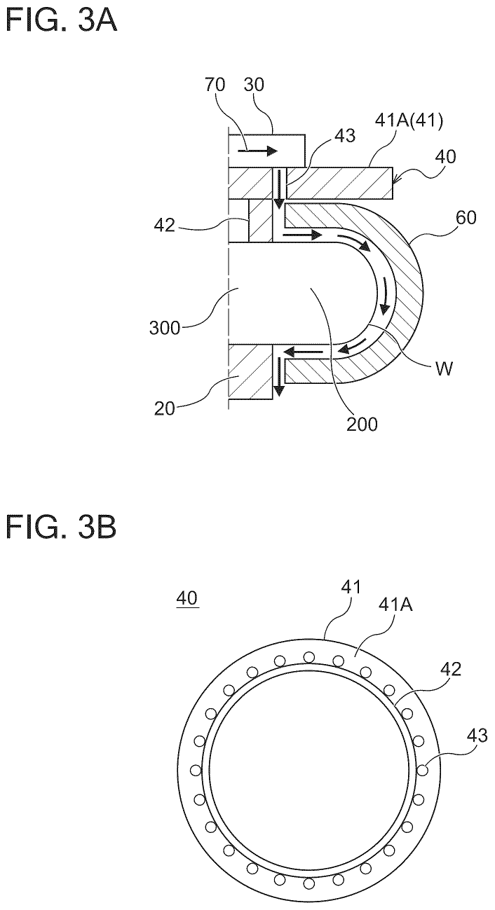

The top cover 40 includes, for example, a tubular portion 42 in a cylindrical shape having a contact portion provided on one end thereof to be brought into contact with the substrate W; and a cover portion 41 in a disk-like shape provided on the other end of the tubular portion 42. In the illustrated example, an outer circumferential portion of the cover portion 41 forms a flange portion 41A that is extended to an outer side of the tubular portion 42. On the outer side of the tubular portion 42 (i.e., in the flange portion 41A), the cover portion 41 has a plurality of gas supply holes 43 that are provided along a circumferential direction thereof (as shown in FIG. 3B). The plurality of gas supply holes 43 are configured to uniformly generate a downflow of the film-forming gas 70 around the circumferential direction. The plurality of gas supply holes 43 are oriented to supply a film-forming gas 70 along the tubular portion 42 and in a vertical direction (i.e., in a direction perpendicular to the substrate W) to an area surrounded by the top cover 40, the bottom cover 50 and the electrode 60 (i.e., to the plasma generation area 71). A buffer chamber 30 is provided on an upper face of the cover portion 41 to uniformize the film-forming gas 70, which is supplied to the outer circumferential portion 200 of the substrate W, around the circumferential direction (around the whole circumference). The buffer chamber 30 may be configured, for example, in a ring shape or in a toric shape having a vacant center portion as shown in FIG. 1. The buffer chamber 30 has an internal space that is fluidically connected with the plurality of gas supply holes 43. The buffer chamber 30 is provided with a supply port 31 that is fluidically connected with the internal space of the buffer chamber 30. The film-forming gas is supplied via the supply port 31 into the buffer chamber 30 and is then distributed from the buffer chamber 30 to the respective gas supply holes 43. This configuration enables the film-forming gas to be uniformly supplied around the circumferential direction through the plurality of gas supply holes 43 to the area surrounded by the top cover 40, the bottom cover 50 and the electrode 60.

A drive shaft 13 of an actuator 12 is fixed to the upper face of the top cover 40. The actuator 12 is placed outside of the plasma chamber 11, and the drive shaft 13 of the actuator 12 is pierced through a wall of the casing 10 and is connected with the top cover 40. A magnetic fluid sealing 14 is provided to seal between the drive shaft 13 and the casing 10. The drive shaft 13 is configured to be vertically movable by the power of the actuator 12. The drive shaft 13 is attached to an actuator main body to be rotatable with the top cover 40 when the substrate W is rotated in the state that the top cover 40 is pressed against the substrate W. When the substrate W is carried into the chamber 11 and is mounted on the stage 20, the actuator 12 works to move the top cover 40 to a retreat position above the stage 20. After the substrate W is mounted on the stage 20, the actuator 12 works to lift down the top cover 40 and bring and press the top cover 40 into contact with and against the substrate W. This configuration causes the top cover 40 to physically separate the plasma generation area 71 and the non-plasma generation area 72 from each other.

According to the embodiment, the substrate W is rotated, such as to uniformize the flow of the film-forming gas 70 in the circumferential direction of the substrate W. This configuration facilitates uniformly forming the protective film 90 around the whole circumference of the outer circumferential portion of the substrate W. According to another embodiment, however, the substrate W may not be rotated. For example, in the case where the electrode 60 is placed continuously around the whole circumference of the substrate W, the substrate W may not be rotated when the protective film 90 is formable around the whole circumference of the outer circumferential portion of the substrate W with the uniformity in an allowable range. In another example, in the case where the electrode 60 is placed intermittently (discretely) around the whole circumference of the substrate W, the substrate W many not be rotated when respective electrode pieces are sufficiently close to one another to such a degree that enables the protective film 90 to be formed around the whole circumference of the outer circumferential portion of the substrate W with the uniformity in an allowable range.

According to the embodiment, the drive shaft 13 of the actuator 12 is fixed to the upper face of the top cover 40. In the case where the buffer chamber 30 is not in a ring shape but is in a disk-like shape, however, the drive shaft 13 of the actuator 12 may be fixed to an upper face of the buffer chamber 30.

The bottom cover 50 is placed on an outer and lateral side of the stage 20 and is configured as a tubular portion in a cylindrical shape that surrounds the whole circumference of the stage 20. The bottom cover 50 is electrically insulated from the stage 20. The bottom cover 50 may be made of a material having plasma resistance, for example, a polyimide, a metal coated with yttria, or another material. An upper face of the bottom cover 50 is flush with the upper face (the mounting surface) of the stage 20. The bottom cover 50 is firmly brought into contact with the substrate W by taking advantage of the force caused by the contact of the top cover 40 with the substrate W, so as to physically isolate the plasma generation area 71. The bottom cover 50 is placed across a predetermined interval from an outer circumferential face of the stage 20. This interval should be such a degree that prevents the plasma from entering a clearance between the bottom cover 50 and the outer circumferential face of the stage 20 to form a film on a lower face of the substrate W.

In the substrate processing apparatus 100 described above, the area surrounded by the top cover 40, the bottom cover 50 and the electrode 60 serves as the plasma generation area 71, and the outer circumferential portion 200 and the center portion 300 of the substrate W are physically divided from each other by the top cover 40 and the bottom cover 50. This configuration clarifies the boundary between the plasma generation area 71 and the plasma non-generation area 72. This configuration accordingly enables the protective film 90 to be formed in a stable film thickness on an inner boundary of the protective film 90 (improves the uniformity in the film thickness) as shown in FIG. 12A and thereby enhances the adhesiveness of the protective film 90. In a comparative example shown in FIG. 12B, on the other hand, the plasma generation area 71 and the plasma non-generation area 72 are separated from each other in a non-physical manner by pressurization of the center portion 300 of the substrate W and/or introduction of a purge gas. This configuration causes an unclear boundary between the two areas and causes incomplete film formation on the inner boundary of the protective film. This decreases the film thickness on the inner boundary of the protective film 90 and lowers the adhesiveness of the protective film 90.

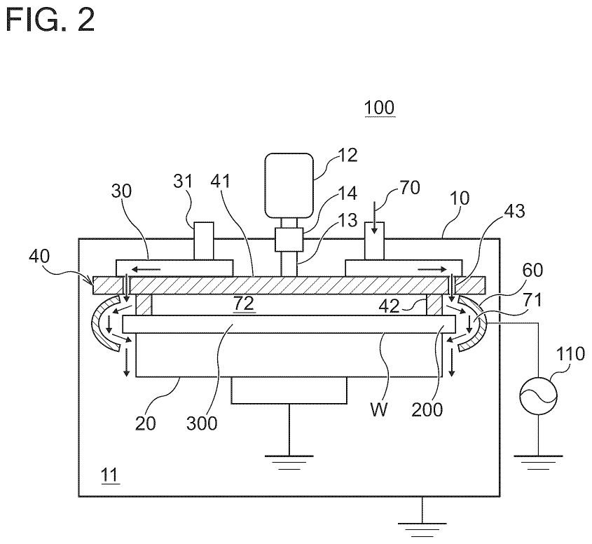

FIG. 2 is a schematic diagram illustrating another configuration example of the substrate processing apparatus 100 according to one embodiment. The substrate processing apparatus 100 of FIG. 2 differs from the substrate processing apparatus 100 of FIG. 1 by the absence of the bottom cover 50. Another difference is extension of the dimension of the mounting surface of the stage 20 to a position approximately equal to an outer circumferential face of the tubular portion 42 of the top cover 40. The other configuration of FIG. 2 is similar to the configuration of FIG. 1, so that the detailed description is omitted. In this substrate processing apparatus 100, in place of the bottom cover 50, the stage 20 serves to separate the plasma generation area 71. More specifically, the plasma generation area 71 is separated by the top cover 40, the stage 20 and the electrode 60. This configuration provides similar functions and advantageous effects to those of the configuration of FIG. 1. This configuration uses the stage 20 as a shielding structure with omission of the bottom cover 50 and thereby advantageously simplifies the apparatus configuration.

FIG. 3A is a sectional view illustrating a configuration example of supplying the film-forming gas. FIG. 3B is a bottom view illustrating a top cover. In this configuration, a plurality of gas supply holes 43 as through holes are provided in the cover portion 41 along the circumferential direction on an outer side of the tubular portion 42 (in the flange portion 41A). It is preferable to provide the plurality of gas supply holes 43 at equal intervals around the circumferential direction, in order to uniformly supply the film-forming gas around the circumferential direction to the plasma generation area 71. In this configuration, the film-forming gas 70 is supplied from the buffer chamber 30 to the plurality of gas supply holes 43 and is then supplied from the respective gas supply holes 43 to the plasma generation area 71 (i.e., to the area surrounded by the top cover 40, the stage 20 (or the bottom cover 50), and the electrode 60). The film-forming gas 70 is used in the plasma generation area 71 for film formation on the outer circumferential portion 200 of the substrate W and subsequently passes through between the stage 20 (or the bottom cover 50) and the electrode 60 to flow downward. FIG. 3A illustrates the example with omission of the bottom cover 50 (shown in FIG. 2), but this configuration is also applicable to the example provided with the bottom cover 50 (shown in FIG. 1).

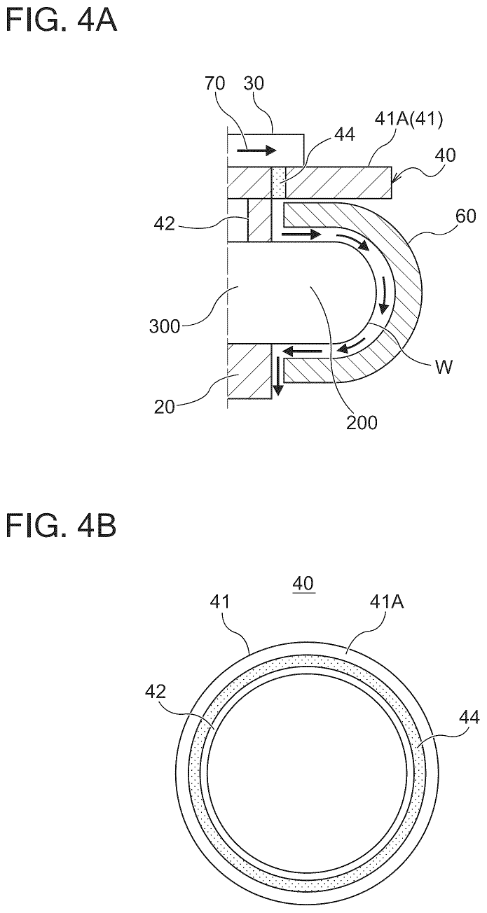

FIG. 4A is a sectional view illustrating another configuration example of supplying the film-forming gas. FIG. 4B is a bottom view illustrating a top cover. In this configuration, a toric porous body 44 is provided in the cover portion 41 on the outer side of the tubular portion 42 (in the flange portion 41A). The porous body 44 is provided to pass through between an upper face and a lower face of the cover portion 41. In the illustrated example, the porous body 44 is continuously provided around the whole circumference. In another example, however, the porous body 44 may be provided intermittently or discretely in the circumferential direction. It is preferable to intermittently or discretely provide the porous bodies 44 at equal intervals around the circumferential direction, in order to uniformly supply the film-forming gas around the circumferential direction to the plasma generation area 71. In this configuration, the film-forming gas 70 is supplied from the buffer chamber 30 to the porous body 44 and is then supplied from the porous body 44 to the plasma generation area 71 (i.e., to the area surrounded by the top cover 40, the stage 20 (or the bottom cover 50), and the electrode 60). The film-forming gas 70 is used in the plasma generation area 71 for film formation on the outer circumferential portion of the substrate W and subsequently passes through between the stage 20 (or the bottom cover 50) and the electrode 60 to flow downward. FIG. 4A illustrates the example with omission of the bottom cover 50 (shown in FIG. 2), but this configuration is also applicable to the example provided with the bottom cover 50 (shown in FIG. 1).

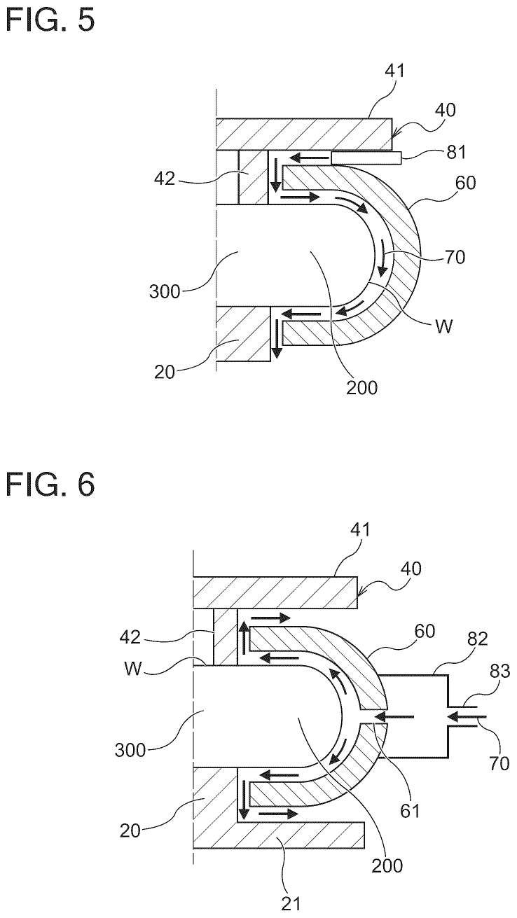

FIG. 5 is a sectional view illustrating another configuration example of supplying the film-forming gas. In this configuration, the film-forming gas 70 is supplied in a horizontal direction from a plurality of nozzles 81 that are placed along the circumferential direction of the substrate W, to a clearance between the electrode 60 and the cover portion 41 (the flange portion 41A) on the outer side of the tubular portion 42. It is preferable to provide the plurality of nozzles 81 at equal intervals around the circumferential direction, in order to uniformly supply the film-forming gas around the circumferential direction to the plasma generation area 71. In this configuration, the film-forming gas 70 is supplied in the horizontal direction from the nozzles 81 to the clearance between the cover portion 41 and the electrode 60, subsequently comes into contact with the tubular portion 41 to change the flow direction to a vertically downward direction and is then supplied to the plasma generation area 71 (i.e., to the area surrounded by the top cover 40, the stage 20 (or the bottom cover 50), and the electrode 60). The film-forming gas 70 is used in the plasma generation area 71 for film formation on the outer circumferential portion of the substrate W and subsequently passes through between the stage 20 (or the bottom cover 50) and the electrode 60 to flow downward. This configuration causes the film-forming gas 70 to flow vertically relative to the tubular portion 42 of the top cover 40 and to be once brought into contact with the tubular portion 42 and thereby enhances the uniformity of the film-forming gas 70. FIG. 5 illustrates the example with omission of the bottom cover 50 (shown in FIG. 2), but this configuration is also applicable to the example provided with the bottom cover 50 (shown in FIG. 1).

FIG. 6 is a sectional view illustrating another configuration example of supplying the film-forming gas. FIG. 6 illustrates the example with omission of the bottom cover 50 (shown in FIG. 2), but this configuration is also applicable to the example provided with the bottom cover 50 (shown in FIG. 1). In this configuration, one or a plurality of gas supply holes 61 are provided in the electrode 60 to supply the film-forming gas 70, in the form of a flow parallel to the face of the substrate W, to the plasma generation area 71. In the case where the electrode 60 is provided continuously or intermittently around the whole circumference of the substrate W, a plurality of gas supply holes 61 are provided in the electrode 60 around the circumferential direction of the substrate W. It is preferable to provide the plurality of gas supply holes 61 at equal intervals around the circumferential direction, in order to uniformly supply the film-forming gas around the circumferential direction to the plasma generation area 71. A buffer chamber 82 is provided on an outer circumferential face of the electrode 60 to be formed in a toric shape around the whole circumference of the electrode 60. The buffer chamber 82 is fluidically connected with the plurality of gas supply holes 61. The film-forming gas 70 is supplied from one or a plurality of gas supply pipes 83 to the buffer chamber 82. Supplying the film-forming gas 70 via the buffer chamber 82 to the respective gas supply holes 61 enables the film-forming gas 70 to be supplied at a uniform flow rate to the respective gas supply holes 61. In this configuration, the film-forming gas 70 is supplied from the gas supply pipes 83 to the buffer chamber 82 and is then supplied from the buffer chamber 82 through the respective gas supply holes 61 to the plasma generation area 71 (i.e., to the area surrounded by the top cover 40, the stage 20 (or the bottom cover 50), and the electrode 60). The film-forming gas 70 supplied to the plasma generation area 71 is split to an upward flow and a downward flow. The upward flow of the film-forming gas 70 flows out through the clearance between the top cover 40 and the electrode 60 and flows out, whereas the downward flow of the film-forming gas 70 passes through between the stage 20 (or the bottom cover 50) and the electrode 60 and flows out.

It is preferable that a flow path for the upward flow and a flow path for the downward flow have substantially identical flow resistances, with a view to causing the film-forming gas 70 flowing through the gas supply hole 61 to the plasma generation area 71 to be split in a vertical direction at equal flow rates. For this purpose, in the illustrated example of FIG. 6, the gas supply hole 61 is provided to be located at an identical height with the substrates W (or the height of the center in a height direction of the substrate W). In the case where the electrode 60 has a vertically symmetrical configuration, the gas supply hole 61 is provided at the center in the height direction of the electrode 60. In the illustrated example of FIG. 6, with a view to making the flow resistances of the flow path for the upward flow and the flow path for the downward flow substantially equal to each other, the stage 20 is provided with an extension portion or a flange portion 21 such as to correspond to the flange portion 41A of the cover portion 41 of the top cover 40. In another example, in place of the flange portion 21 provided in the stage 20, the bottom cover 50 may be provided with a flange portion such as to correspond to the flange portion 41A of the cover portion 41 of the top cover 40.

In the case where the electrode 60 is provided to be opposed to part in the circumferential direction of the outer circumferential portion 200 of the substrate W (as shown in FIGS. 7A and 7B), one gas supply hole 61 may be provided in the electrode 60, and the buffer chamber 82 may be omitted.

FIG. 7A is a sectional view illustrating a configuration example of the electrode 60. FIG. 7B is a plan view illustrating the configuration example of the electrode 60. As shown in these drawings, the electrode 60 may be provided to be opposed to part in the circumferential direction of the outer circumferential portion 200 of the substrate W. In this configuration, the electrode 60 and the plasma generation area 71 on the inner side of the electrode 60 are opposed to the whole circumference of the outer circumferential portion of the substrate W, for example, by rotating the substrate W by means of the stage 20. More specifically, the electrode 60 having dimensions corresponding to the part in the circumferential direction of the outer circumferential portion of the substrate W is placed, and the substrate W is rotated, so that the protective film 90 is formed on the whole circumference of the outer circumferential portion 200 of the substrate W. The substrate W is rotated by a rotating direction shown by an arrow 25. The rotating direction may, however, be a reverse direction or any direction. FIG. 7A illustrates the example provided with the bottom cover 50 (shown in FIG. 1), but this configuration is also applicable to the example with omission of the bottom cover 50 (shown in FIG. 2).

FIG. 8A is a sectional view illustrating a configuration example of the vertically split electrode 60 in an open position. FIG. 8B is a sectional view illustrating the configuration example of the vertically split electrode 60 in a closed position. In the case where the electrode 60 is placed in the toric shape around the whole circumference of the substrate W, the electrode 60 may be vertically split to an upper electrode 60A and a lower electrode 60B, with a view to facilitating mounting of the substrate W onto the stage 20. In this case, for example, the upper electrode 60A may be fixed to the flange portion 41A of the cover portion 41 of the top cover 40 and may be configured to be vertically moved along with the move of the top cover 40 by means of the actuator 12. When the substrate W is to be mounted on the stage 20, as shown in FIG. 8A, the top cover 40 and the upper electrode 60A are moved upward to be retreated. After the substrate W is mounted on the stage 20, the top cover 40 and the upper electrode 60A are moved downward, such that the top cover 40 is brought into contact with the substrate W and that the upper electrode 60A and the lower electrode 60B are joined together to be integrated. This forms the plasma generation area 71 (i.e., the area surrounded by the top cover 40, the stage 20 (or the bottom cover 50), and the electrode 60). This illustrates the example that the plasma generation area 71 is divided by the stage 20 (corresponding to FIG. 2), but this configuration is also applicable to the example that the bottom cover 50 is placed to divide the plasma generation area 71 (corresponding to FIG. 1).

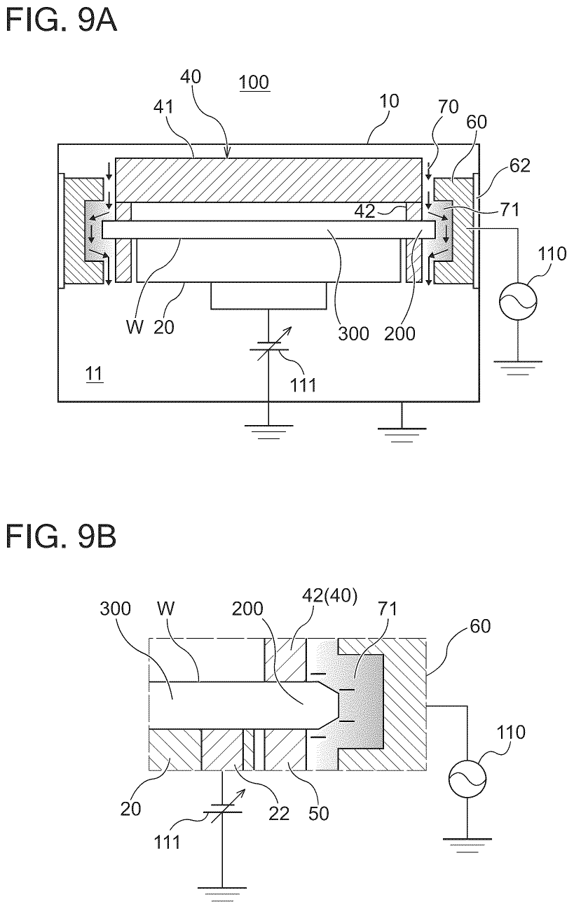

FIG. 9A is a schematic diagram illustrating a connection example of connecting a substrate with a negative bias. According to the embodiment described above, the stage 20 and the substrate W are connected with the ground potential. According to another embodiment, however, the stage 20 and the substrate W may be connected with a lower potential side of a DC power source 111 such as to be biased to a negative DC voltage (negative bias voltage). The DC power source 111 is preferably configured as a power source that is capable of adjusting the negative bias voltage. Applying a negative bias voltage to the substrate W enables negative charges to be accumulated in only the outer circumferential portion 200 of the substrate W opposed to the electrode 60 and thereby accelerates generation of plasma. The center portion 300 of the substrate W is not opposed to the electrode 60, so that no electric charges are accumulated in the center portion 300. In the illustrated example of FIG. 9A, the cover portion 41 of the top cover 40 is not provided with a flange portion, and the film-forming gas is supplied downward from between the top cover 40 and the electrode 60. This connection example is, however, also applicable to the configuration of the embodiment described above. As shown in FIG. 9A, when the electrode 60 is fixed to an inner wall of the casing 10, an insulator 62 may be placed between the electrode 60 and the casing 10 to electrically insulate the electrode 60 and the casing 10 from each other.

FIG. 9B is a schematic diagram illustrating another connection example of connecting a substrate with a negative bias. As shown in FIG. 9B, an electrical conductor 22 that is a component coming into contact with the substrate W and applying a negative bias voltage to the substrate W is placed on the stage 20 at a position close to the outer circumferential portion 200 of the substrate W. The electrical conductor 22 may be an annular (ring-shape) component placed on an inner side of the outer circumferential portion 200 of the substrate W. The electrical conductor 22 may be provided continuously or intermittently corresponding to the whole circumference of the outer circumferential portion 200 of the substrate W. The electrical conductor 22 is connected with a lower potential side of a DC power source 111 and is placed on an outer circumferential portion of the stage 20 to be brought into contact with the substrate W and apply a negative bias voltage to the substrate W. The electrical conductor 22 is electrically insulated from the other part of the stage 20 by means of a non-illustrated insulator or the like, or the stage 20 is configured by an insulator. The electrical conductor 22 is provided to pass through the outer circumferential portion of the stage 20. An upper face of the electrical conductor 22 is flush with the mounting face of the stage 20 (completely flush with the mounting face or slightly protruded from the mounting face), whereas a lower face of the electrical conductor 22 is exposed on a lower face of the stage 20. This configuration efficiently gives a required negative bias voltage to the outer circumferential portion 200 of the substrate W from a position close to the outer circumferential portion 200 of the substrate W. This illustrates the example that the negative bias voltage is applied to the substrate W by the DC power source 111. Another example may apply a negative bias voltage to the substrate W by a pulse power source. FIG. 9B illustrates the example provided with the bottom cover 50 (corresponding to FIG. 1). A modification may, however, omit the bottom cover 50 and may extend the stage 20 to the position of the bottom cover 50. In this modification, the electrical conductor 22 may be brought into contact with the outer circumferential portion 200 of the substrate W.

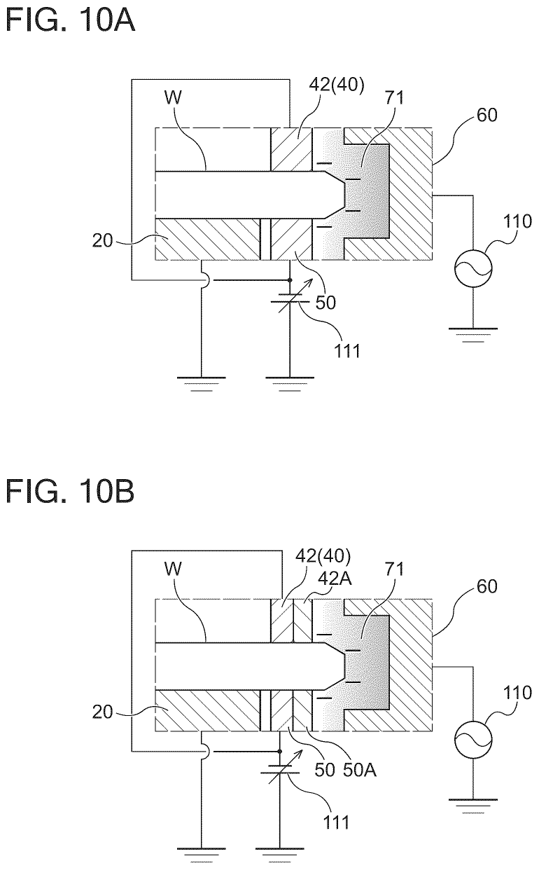

FIG. 10A and FIG. 10B are schematic diagrams illustrating connection examples of biasing the top cover 40 and the bottom cover 50. As shown in FIG. 10A, the top cover 40 and the bottom cover 50 that are brought into contact with the substrate W may be made of an electrical conductor, and the top cover 40 and the bottom cover 50 may be connected with a lower potential side of a DC power source 111 to bias the outer circumferential portion of the substrate W to a negative DC voltage. The stage 20 may be connected with a ground potential. The entireties of the top cover 40 and the bottom cover 50 may be made of an electrical conductor. In another example, at least parts of the top cover 40 and the bottom cover 50 that are brought into contact with the substrate W may be made of an electrical conductor. As shown in FIG. 10B, parts of the top cover 40 and the bottom cover 50 that are exposed to the plasma generation area 71 may be covered with insulators (an insulator 42A and an insulator 50A). This configuration suppresses or prevents the top cover 40 and the bottom cover 50 from being deteriorated by plasma. In a modification, the outer circumferential portion of the substrate W may be biased to a negative DC voltage by using one of the top cover 40 and the bottom cover 50.

The bias is not limited to the DC voltage but may be a pulse or a high-frequency voltage. The negative bias is more likely to attract positive ions. A positive bias is to be applied, in order to attract negative ions.

According to the embodiment, when DLC is employed as the protective film 90, for example, a substrate bias voltage is −500V to −50 V; a film-forming part has a pressure of 0.1 to 1 Pa; and a carbon-containing gas, such as CH₄, C₂H₂, CO or the like, is used as a material gas.

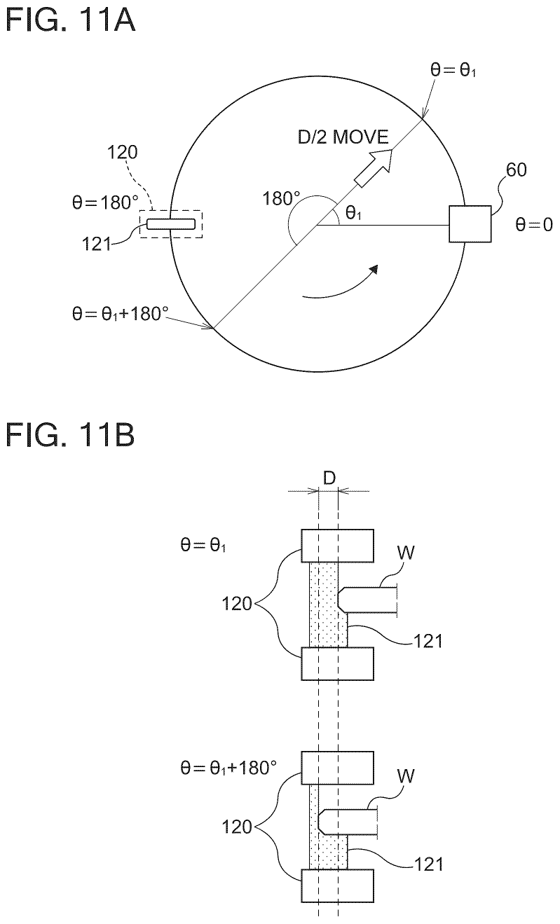

FIG. 11A and FIG. 11B are explanatory diagrams illustrating a method of centering the substrate W. As shown in FIG. 11A, a line sensor 120 is provided at a position of θ=180 degrees on the outer circumference of the substrate W that is placed on the stage 20. The substrate W is rotated by the stage 20, and the line sensor 120 measures distances by which an irradiation area 121 is blocked at positions of θ=θ1 and θ=θ1+180 degrees. An origin θ=0 may be set at any arbitrary position. In the illustrated example of FIG. 11A, the origin θ=0 is set at the position of the electrode 60, which is placed in part of the outer circumferential portion 200 of the substrate W. The line sensor 120 includes a light emitting element 120A and a light receiving element 120B in a pair. The irradiation area 121 is formed by emitting light linearly from the light emitting element 120A toward the light receiving element 120B, and distances or positions by which or at which the substrate W blocks the irradiation area 121 are measured. As shown in FIG. 11B, it is assumed that the distance by which the substrate W blocks the irradiation area 121 of the line sensor 120 at the position of θ=θ1+180 degrees is longer by a distance D than the distance by which the substrate W blocks the irradiation area 121 of the line sensor 120 at the position of θ=θ1. In this case, the center of the substrate W is displaced relative to the center of rotation of the stage 20 by a distance D/2 from the position of θ=θ1 toward the position of θ=θ1+180 degrees. Accordingly, the substrate W is moved by the distance D/2 in an opposite direction from the position of θ=θ1+180 degrees toward the position of θ=1. This configuration adjusts the position of the substrate W to the center of rotation of the stage 20 (centering). This accordingly enables the distance between the outer circumferential portion 200 of the substrate W and the electrode 60 to be readily uniformized over the whole circumference. When the substrate W is rotated relative to the electrode 60 that is placed in part of the outer circumferential portion 200 of the substrate W as shown in FIG. 11A, this configuration enables the outer circumferential portion 200 of the substrate W to be opposed to the electrode 60 by a uniformed distance over the whole circumference.

FIG. 12A is an explanatory diagram schematically illustrating formation of a protective film according to one embodiment. FIG. 12B is an explanatory diagram schematically illustrating formation of a protective film according to a comparative example. In the substrate processing apparatus 100 of the above embodiment, as shown in FIG. 12A, the area surrounded by the top cover 40, the stage 20 (or the bottom cover 50) and the electrode 60 serves as the plasma generation area 71, and the outer circumferential portion 200 and the center portion 300 of the substrate W are physically divided from each other by the top cover 40 and the stage 20 (or the bottom cover 50). This configuration clarifies the boundary between the plasma generation area 71 and the plasma non-generation area 72. This configuration accordingly enables the protective film 90 to be formed in a stable film thickness on an inner boundary of the protective film 90 (improves the uniformity in the film thickness) and thereby enhances the adhesiveness of the protective film 90. FIG. 12A illustrates the example that causes the stage 20 to divide the lower face of the substrate W (shown in FIG. 2), but this configuration is also applicable to the example that causes the bottom cover 50 to divide the lower face of the substrate W (shown in FIG. 1). In the comparative example shown in FIG. 12B, on the other hand, the plasma generation area 71 and the plasma non-generation area 72 are separated from each other in a non-physical manner by pressurization of the center portion 300 of the substrate W and/or introduction of a purge gas. This configuration causes an unclear boundary between the two areas. Such a configuration of separating two areas in a non-physical manner fails to form a stable film on the inner boundary of the protective film 90. This decreases the film thickness on the inner boundary of the protective film 90 and lowers the adhesiveness of the protective film 90.

### Modifications

(1) The above embodiment illustrates the example provided with both the top cover and the bottom cover (shown in FIG. 1) and the example provided with only the top cover (shown in FIG. 2). A modified configuration may, however, be provided with only the bottom cover. In this modified configuration, the bottom cover serves to suppress or prevent a decrease in the film thickness on the inner boundary of the protective film and to suppress or prevent reduction of the adhesiveness of the protective film in at least the lower face of the substrate W. This configuration accordingly improves the quality of the protective film. On an upper face side of the substrate, another shielding technique, such as a resist film, may be employed to prevent formation of a film-forming material in the center portion on the upper face of the substrate.
(2) The above embodiment describes the plasma film forming apparatus. The structure of the above embodiment (the shielding structure by the top cover and/or the bottom cover) is, however, also applicable to a plasma etching apparatus or another plasma substrate processing apparatus.

### Other Embodiments

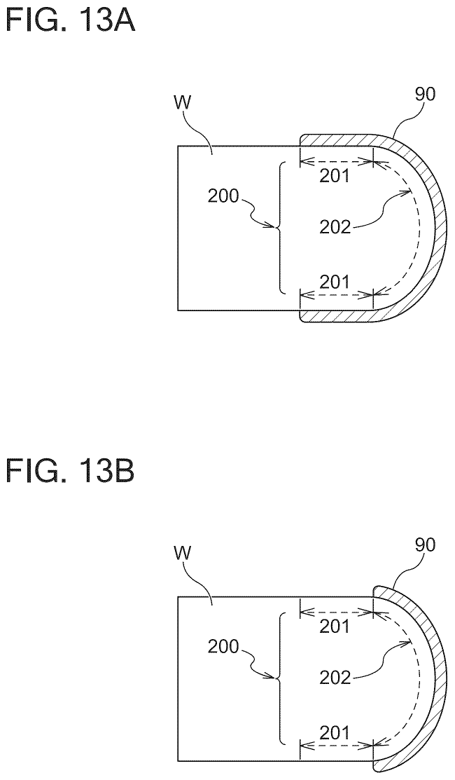

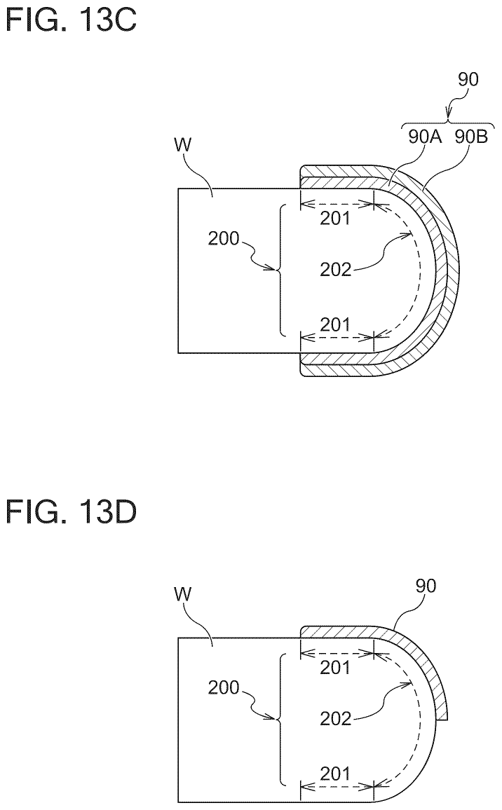

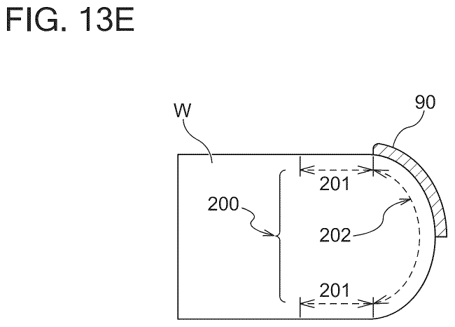

FIGS. 13A to 13E are schematic diagrams illustrating substrates W with protective films formed in various configurations (substrates with protective films). The protective film 90 may be formed along part or the entirety in a radial direction of the outer circumferential portion 200 of the substrate W (for example, along at least one of the edge portion 201 and the bevel portion 202). For example, the protective film 90 may be formed in the edge portion 202 and the bevel portion 202 on both faces or on a single face of the substrate W. In another example, the protective film 90 may be formed in only the bevel portion 202 on both faces or on a single face of the substrate W. In another example, the protective film 90 may be formed in only the edge portion 201 on both faces or on a single face of the substrate W. The protective film 90 may be comprised of a plurality of layers. In the case where a protective film is formed on a single face of the substrate W, it is preferable to form a protective film in part or the entirety in the radial direction of the outer circumferential portion (for example, in at least one of the edge portion 201 and the bevel portion 202) on the face of the substrate W including the device formation area. An area where the protective film 90 is formed (the edge portion 201 and/or the bevel portion 202 on both faces or on a single face of the substrate W) may be an area that needs to be particularly protected in the outer circumferential portion of the substrate or an area that just needs to be protected in the outer circumferential portion of the substrate.

FIG. 13A illustrates an example that a protective film 90 configured by an amorphous carbon film or a DLC film is formed in the edge portion 201 and the bevel portion 202 on both faces of the substrate W. FIG. 13B illustrates an example that a protective film 90 configured by an amorphous carbon film or a DLC film is formed in only the bevel portion 202 on both faces of the substrate W. An area where the protective film 90 is not formed may be protected by one or some in combination of the top cover 40, the bottom cover 50, and the stage 20 described above and a resist film. In the case where the protective film 90 is formed in only the bevel portion 202, for example, the top cover 40 described above serves to shield the center portion 300 and the edge portion 201 from the plasma.

FIG. 13C illustrates an example that a protective film 90 comprised of a plurality of layers including an amorphous carbon film or a DLC film is formed in the edge portion 201 and the bevel portion 202 on both faces of the substrate. In this illustrated example, the protective film 90 includes a first layer 90A formed on the substrate W and a second layer 90B formed on the first layer 90A. In one example of the respective layers, the first layer 90A may be a SiC film, and the second layer 90B may be an amorphous carbon film or a DLC film. For example, when the substrate W is made of a silicon (Si) material or the substrate W has a surface made of silicon (Si), a SiC layer may be formed as the first layer 90A on the silicon, and an amorphous carbon film or a DLC film may further be formed as the second layer 90B.

This SiC layer may be formed by a method such as chemical vapor deposition (CVD) or epitaxial growth. The amorphous carbon film or DLC film may be formed by, the plasma film forming method described above. The area where the protective film 90 is not formed may be protected by one or some in combination of the top cover 40, the bottom cover 50, and the stage 20 described above and a resist film.

The protective film 90 may be comprised of three or more layers. In the case where the protective film 90 is comprised of a plurality of layers, it is preferable that at least an outermost layer is formed by a film having etching resistance and high hardness, such as an amorphous carbon film or a DLC film. The protective film in any embodiment or example may be comprised of a plurality of layers. In this case, it is preferable that at least an outermost layer is formed by a film having etching resistance and high hardness, such as an amorphous carbon film or a DLC film.

FIG. 13D illustrates an example that a protective film 90 including an amorphous carbon film or a DLC film is formed in the edge portion 201 and the bevel portion 202 on a single face of the substrate W. In this illustrated example, the protective film 90 is formed on the upper face of the substrate W. The boundary between the upper face and the lower face of the substrate W in the bevel portion 202 may be, for example, half the thickness of the substrate W. In this example, the protective film 90 may also be comprised of a plurality of layers like the example of FIG. 13C. The area where the protective film 90 is not formed may be protected by one or some in combination of the top cover 40, the bottom cover 50, and the stage 20 described above and a resist film.

FIG. 13E illustrates an example that a protective film 90 including an amorphous carbon film or a DLC film is formed in only the bevel portion 202 on a single face of the substrate W. In this example, the protective film 90 may also be comprised of a plurality of layers like the example of FIG. 13C. The area where the protective film 90 is not formed may be protected by one or some in combination of the top cover 40, the bottom cover 50, and the stage 20 described above and a resist film.

The substrate W with the protective film that includes an amorphous carbon film or a DLC film and that is formed on the outer circumferential portion of the substrate as described above prevents corrosion into the outer circumferential portion of the substrate W, which may occur in a processing step of a semiconductor manufacturing process. Starting the semiconductor manufacturing process by using the substrate with the protective film that includes an amorphous carbon film or a DLC film and that is formed on the outer circumferential portion of the substrate accordingly protects the outer circumferential portion of the substrate from corrosion in all the steps of the semiconductor manufacturing process.

The protective film on the outer circumferential portion of the substrate may be peeled off, prior to a substrate dicing step of the semiconductor manufacturing process. Another configuration may, however, perform the dicing step without peeling off the protective film on the outer circumferential portion of the substrate. The configuration in the latter case can omit a peel-off step of the protective film.

A protective film may be formed on the outer circumferential portion of the substrate, prior to a step that requires protection of the outer circumferential portion of the substrate. For example, a protective film may be formed on the outer circumferential portion of the substrate, prior to an etching step that is likely to cause erosion of the outer circumferential portion of the substrate.

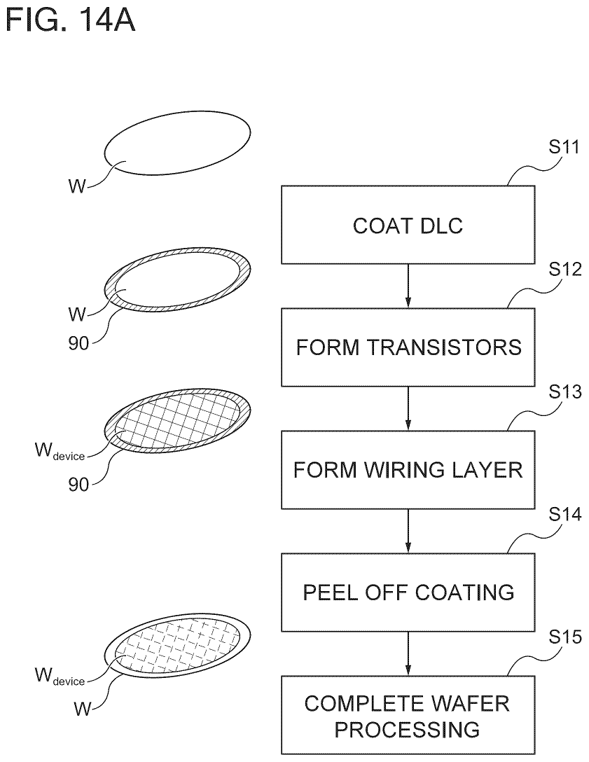

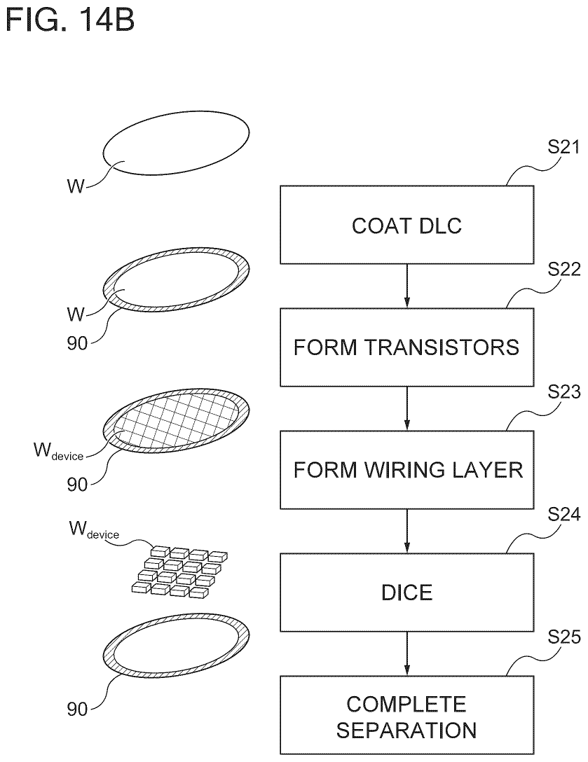

FIG. 14A is a flowchart showing a semiconductor manufacturing process according to one embodiment. This example forms a protective film on the outer circumferential portion of the substrate in a first step of the semiconductor manufacturing process and then performs subsequent steps of the semiconductor manufacturing process. This flow of the semiconductor manufacturing process first forms a protective film 90 including an amorphous carbon film or a DLC film in part or the entirety in a radial direction of the outer circumferential portion of the substrate (step S11). The protective film 90 includes one or a plurality of layers and preferably has an amorphous carbon film or a DLC film as at least an outermost layer. The flow subsequently performs a transistor formation step for the device formation area of the substrate W (step S12) and a wiring layer formation step (step S13) and then peels off the protective film 90 from the substrate W by etching using a chemical solution, dry etching or another technique (step S14). The flow subsequently performs processing of separating a plurality of semiconductor devices (semiconductor chips) W_{device} from the substrate W by dicing or the like and completes the semiconductor manufacturing process (preceding process) (step S15). A modification may provide/purchase a substrate with a protective film formed on an outer circumferential portion of the substrate (a substrate with protective film) and may perform the semiconductor manufacturing process for the substrate with protective film.

FIG. 14B is a flowchart showing a semiconductor manufacturing process according to another embodiment. This example forms a protective film on the outer circumferential portion of the substrate in a first step of the semiconductor manufacturing process and then performs subsequent steps of the semiconductor manufacturing process. This example performs a dicing step without peeling off the protective film formed in the outer circumferential portion of the substrate. This flow of the semiconductor manufacturing process first forms a protective film 90 including an amorphous carbon film or a DLC film in part or the entirety in a radial direction of the outer circumferential portion of the substrate (step S21). The protective film 90 includes one or a plurality of layers and preferably has an amorphous carbon film or a DLC film as at least an outermost layer. The flow subsequently performs a transistor formation step for the device formation area of the substrate W (step S22) and a wiring layer formation step (step S23) and then performs a dicing step to implement processing of, for example, separating a plurality of semiconductor devices (semiconductor chips) from the substrate W and completes the semiconductor manufacturing process (preceding process) (steps S24 and S25). This example allows for omission of the step of peeling off the protective film. A modification may provide/purchase a substrate with a protective film formed on an outer circumferential portion of the substrate (a substrate with protective film) and may perform the semiconductor manufacturing process for the substrate with protective film.

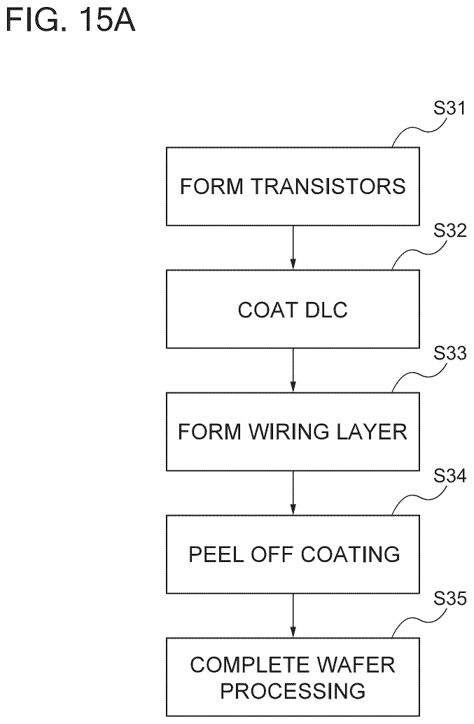

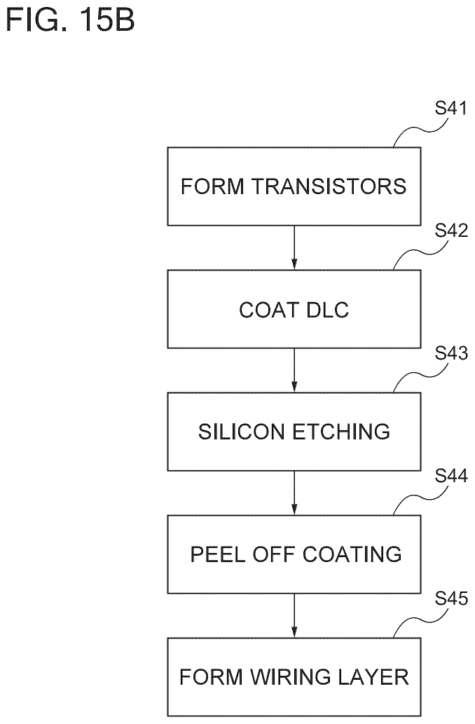

FIG. 15A is a flowchart showing a semiconductor manufacturing process according to another embodiment. This example forms a protective film including an amorphous carbon film or a DLC film on an outer circumferential portion of a substrate, prior to a wiring layer formation step and thereby protects the outer circumferential portion of the substrate from corrosion in the wiring layer formation step. More specifically, after completion of a transistor formation step (step S31) in the semiconductor manufacturing process, the flow forms a protective film 90 including an amorphous carbon film or a DLC film in part or the entirety in a radial direction of the outer circumferential portion of the substrate (step S32). The protective film 90 includes one or a plurality of layers and preferably has an amorphous carbon film or a DLC film as at least an outermost layer. The flow subsequently performs a wiring layer formation step (step S33) for the substrate W after formation of the protective film and then peels off the protective film 90 from the substrate W by etching using a chemical solution, dry etching or another technique (step S34). The flow then performs a dicing step to implement processing of, for example, separating a plurality of semiconductor devices (semiconductor chips) from the substrate W and completes the semiconductor manufacturing process (preceding process) (step S35).

FIG. 15B is a flowchart showing a semiconductor manufacturing process according to another embodiment. This example forms a protective film including an amorphous carbon film or a DLC film on an outer circumferential portion of a substrate, prior to a silicon etching step and thereby protects the outer circumferential portion of the substrate from corrosion in the silicon etching step. More specifically, after completion of a transistor formation step (step S41) in the semiconductor manufacturing process, the flow forms a protective film 90 including an amorphous carbon film or a DLC film in part or the entirety in a radial direction of the outer circumferential portion of the substrate (step S42). The protective film 90 includes one or a plurality of layers and preferably has an amorphous carbon film or a DLC film as at least an outermost layer. The flow subsequently performs a silicon etching step for the substrate W after formation of the protective film (step S43) and then peels off the protective film 90 from the substrate W by etching using a chemical solution, dry etching or another technique (step S44). The flow then performs subsequent steps including a wiring layer formation step for the substrate W (step S45).

In the illustrated examples of FIG. 15A and FIG. 15B, a protective film including an amorphous carbon film or a DLC film is formed in the outer circumferential portion of the substrate, prior to the wiring layer formation step or prior to the silicon etching step. A modification may form a protective film including an amorphous carbon film or a DLC film in the outer circumferential portion of the substrate, prior to another processing step.

The configuration of the above embodiments provide (purchase) a substrate with a protective film formed in part or the entirety in a radial direction of an outer circumferential portion of the substrate and subsequently performs a semiconductor manufacturing process. This prevents corrosion into the outer circumferential portion of the substrate W, which may occur in a processing step of the semiconductor manufacturing process. Formation of a protective film in the outer circumferential portion of the substrate prior to a step that requires protection of the outer circumferential portion of the substrate prevents corrosion into the outer circumferential portion of the substrate W, which may occur in this step.

At least the following technical ideas are comprehended from the description of the above embodiments.
[1] According to one aspect, there is provided a method of forming a protective film on an outer circumferential portion including a bevel portion of a substrate by using a plasma. The method comprises: placing the substrate having a first face and a second face that are opposed to each other, on a stage having smaller dimensions than dimensions of the substrate, such as to bring the second face of the substrate into contact with the stage and to cause an outer circumferential portion of the substrate to be protruded from an outer edge of the stage; causing at least part in a circumferential direction of the outer circumferential portion of the substrate to be opposed to an electrode; causing a first shielding structure that separates the outer circumferential portion of the substrate from an inner side area on an inner side of the outer circumferential portion of the substrate to come into contact with the first face of the substrate, and/or, causing a second shielding structure that separates the outer circumferential portion of the substrate from the inner side area of the substrate to come into contact with the second face of the substrate; and supplying a film-forming gas to between the outer circumferential portion of the substrate and the electrode, so as to form a protective film on the outer circumferential portion of the substrate.

The method of this aspect enables a protective film to be formed on the outer circumferential portion of the substrate in a state that a portion other than the outer circumferential portion (i.e., a center portion) on the first face and/or the second face of the substrate is physically shielded by the first shield structure and/or the second shield structure. This configuration causes a plasma generation area (the outer circumferential portion) and a plasma non-generation area (the center portion) on the substrate to be separated from each other by a physical structure. This accordingly suppresses or prevents a decrease in film thickness on an inner boundary of the protective film and reduction of the adhesiveness.

For example, an area surrounded by the first shielding structure, the electrode, and the stage or the second shielding structure is specified as the plasma generation area. A protective film may be formed on the outer circumferential portion of the substrate in the state that the portion other than the outer circumferential portion (i.e., the center portion) of the substrate is shielded by the first shielding structure and the stage or the second shielding structure. The configuration of separating the plasma generation area (the outer circumferential portion) and the plasma non-generation area (the center portion) from each other by the physical structure on the substrate suppresses or prevents a decrease in film thickness on the inner boundary of the protective film and reduction of the adhesiveness.

A modified configuration may be provided with the second shielding structure only on the second face of the substrate, while omitting the first shielding structure on the first face of the substrate, in order to suppress or prevent a decrease in film thickness on the inner boundary of the protective film and reduction of the adhesiveness with regard to the second face. This modified configuration suppresses or prevents a decrease in film thickness on the inner boundary of the protective film and reduction of the adhesiveness with regard to at least the second face of the substrate and thereby improves the quality of the protective film.
[2] According to one aspect, the method of the above aspect may comprise causing the first shielding structure to come into contact with the first face of the substrate, wherein the first shielding structure may comprise a contact portion that is brought into contact with the substrate; and a hollow portion that is provided on an inner side of the contact portion and that is configured to form a shielding space, along with the substrate, wherein an inner side area on the inner side of the outer circumferential portion of the substrate may be placed in the hollow portion.

The method of this aspect enables a portion on the inner side of the outer circumferential portion (i.e., the center portion) of the substrate to be placed in the hollow portion. This configuration accordingly assures protection of a device formation area of the substrate without coming into contact with the first shielding structure and thereby suppresses or prevents deterioration of the device formation area.
[3] According to one aspect, in the method of the above aspect, the first shielding structure may comprise a tubular portion that is brought into contact with the substrate; and a cover portion that is configured to close one end side of the tubular portion, wherein the other end side of the tubular portion may be brought into contact with the substrate.

The method of this aspect enables the first shielding structure to be formed by a simple configuration.
[4] According to one aspect, in the method of the above aspect, the cover portion may be extended to an outer side of the tubular portion, and the film-forming gas may be supplied to between the outer circumferential portion of the substrate and the electrode via a plurality of gas supply holes, which are provided in the cover portion to be placed on the outer side of the tubular portion and along the outer circumferential portion of the substrate.

The method of this aspect enables the film-forming gas to be uniformly supplied to a plasma generation area (an area surrounded by the first shielding structure, the electrode, and the stage or the second shielding structure) by the simple configuration.
[5] According to one aspect, in the method of the above aspect, the film-forming gas may be supplied to the plurality of gas supply holes via a buffer chamber that is provided on an outer side of the cover portion to communicate with the plurality of gas supply holes.

The method of this aspect causes the film-forming gas to be supplied via the buffer chamber to the plurality of gas supply holes and thereby enables the film-forming gas to be uniformly supplied to the respective gas supply holes. This configuration accordingly enables the film-forming gas to be uniformly supplied over the entirety in a circumferential direction of the plasma generation area.
[6] According to one aspect, in the method of the above aspect, the cover portion may be extended to an outer side of the tubular portion, and the film-forming gas may be supplied to between the outer circumferential portion of the substrate and the electrode via a porous body, which is placed in a toric shape on the outer side of the tubular portion to pass through the cover portion.

The method of this aspect enables the film-forming gas to be uniformly supplied to the plasma generation area (the area surrounded by the first shielding structure, the electrode, and the stage or the second shielding structure) by the simple configuration.
[7] According to one aspect, in the method of the above aspect, the film-forming gas may be supplied to the porous body via a buffer chamber that is provided on an outer side of the cover portion to communicate with the porous body.

The method of this aspect causes the film-forming gas to be supplied via the buffer chamber to the porous body in the toric shape and thereby enables the film-forming gas to be uniformly supplied to over the entirety in a circumferential direction of the porous body in the toric shape. This configuration accordingly enables the film-forming gas to be uniformly supplied over the entirety in the circumferential direction of the plasma generation area.
[8] According to one aspect, in the method of the above aspect, the cover portion may be extended to an outer side of the tubular portion, and the film-forming gas may be supplied to between the cover portion and the electrode on the outer side of the tubular portion, may be made to collide with the tubular portion, and may subsequently be supplied to between the outer circumferential portion of the substrate and the electrode.

The method of this aspect causes the film-forming gas to flow perpendicularly to the tubular portion of the first shielding structure and to once collide with the tubular portion. This configuration enhances the uniformity of the film-forming gas. Furthermore, the method of this aspect enables the film-forming gas to be uniformly supplied to the plasma generation area (the area surrounded by the first shielding structure, the electrode, and the stage or the second shielding structure) without providing the first shielding structure with gas supply holes or a flow path of a porous body. This simplifies the configuration of the first shielding structure.
[9] According to one aspect, in the method of the above aspect, the film-forming gas may be supplied from a lateral side of the substrate to between the outer circumferential portion of the substrate and the electrode via one or a plurality of gas supply holes provided in the electrode.

The method of this aspect causes the film-forming gas to be supplied from the lateral direction to the plasma generation area via the gas supply hole or holes provided in the electrode and thereby enables the film-forming gas to be uniformly supplied to the entirety of the plasma generation area. Furthermore, the method of this aspect enables the film-forming gas to be uniformly supplied to the plasma generation area without providing the first shielding structure with gas supply holes or a flow path of a porous body. This simplifies the configuration of the first shielding structure.
[10] According to one aspect, in the method of the above aspect, a plurality of gas supply holes may be provided in the electrode, and the film-forming gas may be supplied to the plurality of gas supply holes via a buffer chamber that is provided on an outer side of the electrode to communicate with the plurality of gas supply holes.

The method of this aspect causes the film-forming gas to be supplied via the buffer chamber to the plurality of gas supply holes provided in the electrode and thereby enables the film-forming gas to be uniformly supplied to the respective gas supply holes. This configuration accordingly enables the film-forming gas to be uniformly supplied over the entirety in a circumferential direction of the plasma generation area.
[11] According to one aspect, in the method of the above aspect, an area surrounded by the first shielding structure, the stage and the electrode may serve as a plasma generation area.

The method of this aspect uses the stage as part of the structure for defining the plasma generation area and accordingly allows for omission of a shielding structure on one face of the substrate. More specifically, this configuration allows for omission of the second shielding structure on the second face side of the substrate.
[12] According to one aspect, in the method of the above aspect, an area surrounded by the first shielding structure, the second shielding structure and the electrode may serve as a plasma generation area.

The method of this aspect ensures flexible design of the structure for defining the plasma generation area on each face of the substrate.
[13] According to one aspect, in the method of the above aspect, the electrode may be split into an upper electrode and a lower electrode, wherein the substrate may be placed on the stage in a state that the upper electrode and the lower electrode are separated from each other, and after the substrate is placed on the stage, the upper electrode and the lower electrode may be joined together to be integrated with each other.

The method of this aspect facilitates mounting and demounting of the substrate when the electrode is provided over the whole circumference of the substrate.
[14] According to one aspect, in the method of the above aspect, the stage may be connected with a ground potential, with a negative potential, or with a positive potential.

The method of this aspect enables a ground potential, a negative potential or a positive potential to be supplied to the outer circumferential portion of the substrate where the protective film is formed. This configuration causes negative charges/positive charges to be accumulated in the outer circumferential portion of the substrate and is more likely to attract positive ions/negative ions included in the film-forming gas. This accelerates generation of the protective film.
[15] According to one aspect, in the method of the above aspect, a first electrical conductor, which is placed on an outer circumferential portion of the stage such as to electrically come into contact with the outer circumferential portion of the substrate or with an inner side of the circumferential portion, may be connected with a ground potential, with a negative potential, or with a positive potential.

The method of this aspect enables a ground potential, a negative potential or a positive potential to be efficiently supplied to the outer circumferential portion of the substrate where the protective film is formed.
[16] According to one aspect, in the method of the above aspect, at least part of the first shielding structure and/or the second shielding structure, which is brought into contact with the substrate, may be an electrical conductor, and the electrical conductor part of the first shielding structure and/or the second shielding structure may be connected with a ground potential, with a negative potential, or with a positive potential.

The method of this aspect enables a ground potential, a negative potential or a positive potential to be efficiently supplied to the outer circumferential portion of the substrate where the protective film is formed by using the first shielding structure and/or the second shielding structure that comes into contact with a boundary between the outer circumferential portion and the center portion of the substrate. This configuration does not need to separately provide an electrical conductor for supplying a potential to the outer circumferential portion of the substrate.
[17] According to one aspect, the method of the above aspect may comprise causing the second shielding structure to come into contact with the second face of the substrate, wherein the second shielding structure may be brought into contact with the second face of the substrate on an outer side of the stage.

The method of this aspect ensures flexible design of a structure that is provided to separate the plasma generation area on the second face of the substrate.
[18] According to one aspect, in the method of the above aspect, the protective film may be formed on the outer circumferential portion of the substrate, while the substrate is rotated.

The method of this aspect enables the film-forming gas to be more uniformly supplied over the entire circumferential direction of the plasma generation area and thereby enables the film-forming gas and the plasma to be more uniformly brought into contact with the outer circumferential portion of the substrate over the entire circumferential direction. This enables a protective film to be more uniformly formed over the entire circumference in the outer circumferential portion of the substrate.
[19] According to one aspect, in the method of the above aspect, the electrode may have such a shape and an arrangement that a distance between the outer circumferential portion of the substrate and the electrode is fixed over a film-forming area of the substrate in a section along a radial direction of the substrate. The electrode has, for example, an arc-like sectional shape.

In the method of this aspect, the distance between the electrode and the outer circumferential portion of the substrate is fixed over the film-forming area. This configuration enables a protective film having a uniform film thickness to be formed over the entire outer circumferential portion of the substrate.
[20] According to one aspect, in the method of the above aspect, the electrode may be placed continuously or intermittently around a whole circumference of the outer circumferential portion of the substrate.

In the method of this aspect, the electrode is placed over the entirety in the circumferential direction of the outer circumferential portion of the substrate. This configuration stably maintains a constant distance between the electrode and the outer circumferential portion of the substrate and thereby further improves the uniformity in film thickness of the protective film.
[21] According to one aspect, in the method of the above aspect, the electrode may be placed in part in a circumferential direction of the outer circumferential portion of the substrate, and the protective film may be formed around entirety in the circumferential direction of the outer circumferential portion of the substrate by rotating the substrate.

In the method of this aspect, the electrode is placed in part in the circumferential direction of the outer circumferential portion of the substrate. This facilitates the arrangement of the electrode.
[22] According to one aspect, in the method of the above aspect, the protective film may include at least one of an insulating film, a dielectric film, a conductor film, and an organic film. The protective film may include a plurality of different types of layers.

The method of this aspect can form a variety of protective films suitable for protecting the outer circumferential portion of the substrate in a substrate processing step after formation of the protective film.
[23] According to one aspect, in the method of the above aspect, the protective film may include a layer made of amorphous carbon or diamond-like carbon.

The method of this aspect causes amorphous carbon or DLC (diamond-like carbon) having favorable etching resistance and favorable hardness to be used for the protective film (in the case where the protective film has a plurality of layers, for at least an outermost layer). This configuration enables the outer circumferential portion of the substrate to be appropriately protected in a substrate processing step after formation of the protective film.
[24] According to one aspect, there is provided a substrate processing apparatus configured to form a protective film on an outer circumferential portion including a bevel portion of a substrate by using a plasma. The substrate processing apparatus comprises: a stage having smaller dimensions than dimensions of the substrate, wherein the substrate having a first face and a second face that are opposed to each other, is placed on the stage such as to bring the second face of the substrate into contact with the stage and to cause the outer circumferential portion of the substrate to be protruded from an outer edge of the stage; an electrode that is placed to the outer circumferential portion of the substrate, such as to be opposed to at least part in a circumferential direction of the outer circumferential portion of the substrate; a first shielding structure configured to come into contact with the first face of the substrate and to separate the outer circumferential portion of the substrate from an inner side area on an inner side of the outer circumferential portion of the substrate, and/or a second shielding structure configured to come into contact with the second face of the substrate and to separate the outer circumferential portion of the substrate from the inner side area of the substrate; and a gas supply device configured to supply a film-forming gas to between the outer circumferential portion of the substrate and the electrode.

The substrate processing apparatus of this aspect enables a protective film to be formed on the outer circumferential portion of the substrate in a state that a portion other than the outer circumferential portion (i.e., a center portion) on the first face and/or the second face of the substrate is physically shielded by the first shield structure and/or the second shield structure. This configuration causes a plasma generation area (the outer circumferential portion) and a plasma non-generation area (the center portion) on the substrate to be separated from each other by a physical structure. This accordingly suppresses or prevents a decrease in film thickness on an inner boundary of the protective film and reduction of the adhesiveness.

For example, an area surrounded by the first shielding structure, the electrode, and the stage or the second shielding structure is specified as the plasma generation area. A protective film may be formed on the outer circumferential portion of the substrate in the state that the portion other than the outer circumferential portion (i.e., the center portion) of the substrate is shielded by the first shielding structure and the stage or the second shielding structure. The configuration of separating the plasma generation area (the outer circumferential portion) and the plasma non-generation area (the center portion) from each other by the physical structure on the substrate suppresses or prevents a decrease in film thickness on the inner boundary of the protective film and reduction of the adhesiveness.

A modified configuration may be provided with the second shielding structure only on the second face of the substrate, while omitting the first shielding structure on the first face of the substrate, in order to suppress or prevent a decrease in film thickness on the inner boundary of the protective film and reduction of the adhesiveness with regard to the second face. This modified configuration suppresses or prevents a decrease in film thickness on the inner boundary of the protective film and reduction of the adhesiveness with regard to at least the second face of the substrate and thereby improves the quality of the protective film.
[25] According to one aspect, there is provided a substrate, comprising a protective film formed on an outer circumferential portion of the substrate, wherein the protective film includes one or a plurality of layers, and at least an outermost layer out of the one or plurality of layers is an amorphous carbon film or a diamond-like carbon or DLC film. In the case where the protective film has a single layer, the entire protective film is an outermost layer configured by an amorphous carbon film or a DLC film. A partial area in a substrate radial direction of the outer circumferential portion, i.e., at least one of an edge portion and a bevel portion, may be covered with a protective film.

The configuration of this aspect causes the outer circumferential portion of the substrate to be covered with an amorphous carbon film or a DLC film having etching resistance and high hardness. This configuration protects the outer circumferential portion of the substrate from corrosion in a semiconductor manufacturing process.
[26] According to one aspect, in the substrate of the above aspect, the protective film may include a plurality of layers, and at least an outermost layer out of the plurality of layers may be an amorphous carbon film or a DLC film.

In the substrate of this aspect, the protective film is comprised of a plurality of layers. For example, one or a plurality of base films are formed on the substrate, and an amorphous film or a DLC film is formed on the base films. This configuration improves the adhesiveness of the amorphous carbon film or the DLC film to the substrate.
[27] According to one aspect, in the substrate of the above aspect, the protective film may include a first layer and a second layer formed on the first layer, and the second layer may be an amorphous carbon film or a DLC film.

In the substrate of this aspect, the protective film is comprised of two layers, and the second layer as the outermost layer is configured by an amorphous carbon film or a DLC film. This configuration has the functions and the advantageous effects described above.
[28] According to one aspect, in the substrate of the above aspect, the substrate may be a silicon substrate, and the first layer may be a SiC film.

In the substrate of this aspect, a SiC film is formed as a base film on a silicon substrate. This improves the adhesiveness of the amorphous carbon film or the DLC film to the substrate.
[29] According to one aspect, in the substrate of the above aspect, the protective film may be formed in only the bevel portion of the substrate.

The configuration of this aspect reduces the area where the protective film is formed, in the case where the bevel portion of the substrate needs to be particularly protected or in the case where it is sufficient to protect the bevel portion.
[30] According to one aspect, in the substrate of the above aspect, the protective film may be formed in only the bevel portion on one face side of the substrate.

The configuration of this aspect reduces the area where the protective film is formed, in the case where the bevel portion on one face side of the substrate (for example, on a face side with a device formation area) needs to be particularly protected or in the case where it is sufficient to protect the bevel portion on a single face side of the substrate.

Although the embodiments of the present invention have been described based on some examples, the embodiments of the invention described above are presented to facilitate understanding of the present invention, and do not limit the present invention. The present invention can be altered and improved without departing from the subject matter of the present invention, and it is needless to say that the present invention includes equivalents thereof. In addition, it is possible to arbitrarily combine or omit the embodiments and the modifications described above and it is also possible to arbitrarily combine or omit respective constituent elements described in the claims and the specification in a range where at least a part of the above-mentioned problem can be solved or a range where at least a part of the effect is exhibited.

The present application claims priority based on Japanese patent application No. 2023-090817 filed on Jun. 1, 2023. The entire disclosure of Japanese Patent Application No. 2023-090817 filed on Jun. 1, 2023, including the specification, claims, drawings and abstract, are incorporated herein by reference in its entirety.

The entire disclosures of Japanese Patent No. 3949941 (PTL 1), Japanese Patent No. 5982383 (PTL 2), and Japanese Unexamined Patent Publication No. 2020-021931 (PTL 3) including the specifications, claims, drawings and abstracts are incorporated herein by reference in its entirety.

### REFERENCE SIGNS LIST

10 casing
11 plasma chamber
12 actuator
13 drive shaft
14 magnetic fluid sealing
20 stage
22 electrical conductor
30 buffer chamber
31 supply port
40 top cover
41 cover portion
41A flange portion
42 tubular portion
42A insulator
43 gas supply hole
44 porous body
50 bottom cover
50A insulator
60 electrode
60A upper electrode
60B lower electrode
61 gas supply hole
62 insulator
70 film-forming gas
71 plasma generation area
72 plasma non-generation area
81 nozzle
82 buffer chamber
83 gas supply pipe
90 protective film
90A first layer
90B second layer
100 substrate processing apparatus
110 RF power source
111 DC power source
120 line sensor
200 outer circumferential portion
201 edge portion
202 bevel portion
300 center portion

1. A method of forming a protective film on an outer circumferential portion including a bevel portion of a substrate by using a plasma, the method comprising:
placing the substrate having a first face and a second face that are opposed to each other, on a stage having smaller dimensions than dimensions of the substrate, such as to bring the second face of the substrate into contact with the stage and to cause the outer circumferential portion of the substrate to be protruded from an outer edge of the stage;
causing at least part in a circumferential direction of the outer circumferential portion of the substrate to be opposed to an electrode;
causing a first shielding structure that separates the outer circumferential portion of the substrate from an inner side area on an inner side of the outer circumferential portion of the substrate to come into contact with the first face of the substrate, and/or, causing a second shielding structure that separates the outer circumferential portion of the substrate from the inner side area of the substrate to come into contact with the second face of the substrate; and
supplying a film-forming gas to between the outer circumferential portion of the substrate and the electrode, so as to form a protective film on the outer circumferential portion of the substrate.

2. The method according to claim 1, comprising
causing the first shielding structure to come into contact with the first face of the substrate, wherein
the first shielding structure comprises a contact portion that is brought into contact with the substrate; and a hollow portion that is provided on an inner side of the contact portion and that is configured to form a shielding space, along with the substrate, wherein
an inner side area on the inner side of the outer circumferential portion of the substrate is placed in the hollow portion.

3. The method according to claim 2,
wherein the first shielding structure comprises a tubular portion that is brought into contact with the substrate; and a cover portion that is configured to close one end side of the tubular portion, wherein
the other end side of the tubular portion is brought into contact with the substrate.

4. The method according to claim 3,
wherein the cover portion is extended to an outer side of the tubular portion, and the film-forming gas is supplied to between the outer circumferential portion of the substrate and the electrode via a plurality of gas supply holes, which are provided in the cover portion to be placed on the outer side of the tubular portion and along the outer circumferential portion of the substrate.

5. The method according to claim 4,
wherein the film-forming gas is supplied to the plurality of gas supply holes via a buffer chamber that is provided on an outer side of the cover portion to communicate with the plurality of gas supply holes.

6. The method according to claim 3,
wherein the cover portion is extended to an outer side of the tubular portion, and the film-forming gas is supplied to between the outer circumferential portion of the substrate and the electrode via a porous body, which is placed in a toric shape on the outer side of the tubular portion to pass through the cover portion.

7. The method according to claim 6,
wherein the film-forming gas is supplied to the porous body via a buffer chamber that is provided on an outer side of the cover portion to communicate with the porous body.

8. The method according to claim 3,
wherein the cover portion is extended to an outer side of the tubular portion, and
the film-forming gas is supplied to between the cover portion and the electrode on the outer side of the tubular portion, is made to collide with the tubular portion, and is subsequently supplied to between the outer circumferential portion of the substrate and the electrode.

9. The method according to claim 1,
wherein the film-forming gas is supplied from a lateral side of the substrate to between the outer circumferential portion of the substrate and the electrode via one or a plurality of gas supply holes provided in the electrode.

10. The method according to claim 9,
wherein a plurality of gas supply holes are provided in the electrode, and
the film-forming gas is supplied to the plurality of gas supply holes via a buffer chamber that is provided on an outer side of the electrode to communicate with the plurality of gas supply holes.

11. The method according to claim 1,
wherein an area surrounded by the first shielding structure, the stage and the electrode serves as a plasma generation area.

12. The method according to claim 1,
wherein an area surrounded by the first shielding structure, the second shielding structure and the electrode serves as a plasma generation area.

13. The method according to claim 1,
wherein the electrode is split into an upper electrode and a lower electrode, wherein
the substrate is placed on the stage in a state that the upper electrode and the lower electrode are separated from each other, and
after the substrate is placed on the stage, the upper electrode and the lower electrode are joined together to be integrated with each other.

14. The method according to claim 1,
wherein the stage is connected with a ground potential, with a negative potential, or with a positive potential.

15. The method according to claim 1,
wherein a first electrical conductor, which is placed on an outer circumferential portion of the stage such as to electrically come into contact with the outer circumferential portion of the substrate or with an inner side of the circumferential portion, is connected with a ground potential, with a negative potential, or with a positive potential.

16. The method according to claim 1,
wherein at least part of the first shielding structure and/or the second shielding structure, which is brought into contact with the substrate, is an electrical conductor, and
the electrical conductor part of the first shielding structure and/or the second shielding structure is connected with a ground potential, with a negative potential, or with a positive potential.

17. The method according to claim 1, comprising
causing the second shielding structure to come into contact with the second face of the substrate, wherein
the second shielding structure is brought into contact with the second face of the substrate on an outer side of the stage.

18. The method according to claim 1,
wherein the protective film is formed on the outer circumferential portion of the substrate, while the substrate is rotated.

19. The method according to claim 1,
wherein the electrode has such a shape and an arrangement that a distance between the outer circumferential portion of the substrate and the electrode is fixed over a film-forming area of the substrate in a section along a radial direction of the substrate.

20. The method according to claim 1,
wherein the electrode is placed continuously or intermittently around a whole circumference of the outer circumferential portion of the substrate.

21. The method according to claim 1,
wherein the electrode is placed in part in a circumferential direction of the outer circumferential portion of the substrate, and
the protective film is formed around entirety in the circumferential direction of the outer circumferential portion of the substrate by rotating the substrate.

22. The method according to claim 1,
wherein the protective film includes at least one of an insulating film, a dielectric film, a conductor film, and an organic film.

23. The method according to claim 22,
wherein the protective film includes a layer made of amorphous carbon or diamond-like carbon.

24. A substrate processing apparatus configured to form a protective film on an outer circumferential portion including a bevel portion of a substrate by using a plasma, the substrate processing apparatus comprising:
a stage having smaller dimensions than dimensions of the substrate, wherein the substrate having a first face and a second face that are opposed to each other, is placed on the stage such as to bring the second face of the substrate into contact with the stage and to cause the outer circumferential portion of the substrate to be protruded from an outer edge of the stage;
an electrode that is placed to the outer circumferential portion of the substrate, such as to be opposed to at least part in a circumferential direction of the outer circumferential portion of the substrate;
a first shielding structure configured to come into contact with the first face of the substrate and to separate the outer circumferential portion of the substrate from an inner side area on an inner side of the outer circumferential portion of the substrate, and/or a second shielding structure configured to come into contact with the second face of the substrate and to separate the outer circumferential portion of the substrate from the inner side area of the substrate; and
a gas supply device configured to supply a film-forming gas to between the outer circumferential portion of the substrate and the electrode.

25. A substrate, comprising:
a protective film formed on only an outer circumferential portion of the substrate, wherein
the protective film includes one or a plurality of layers, and
at least an outermost layer out of the one or plurality of layers is an amorphous carbon film or a diamond-like carbon or DLC film.

26. The substrate according to claim 25,
wherein the protective film includes a plurality of layers, and at least an outermost layer out of the plurality of layers is an amorphous carbon film or a DLC film.

27. The substrate according to claim 26,
wherein the protective film includes a first layer and a second layer formed on the first layer, and the second layer is an amorphous carbon film or a DLC film.

28. The substrate according to claim 27,
wherein the substrate is a silicon substrate, and
the first layer is a SiC film.

29. The substrate according to claim 25,
wherein the protective film is formed in only the bevel portion of the substrate.

30. The substrate according to claim 29,
wherein the protective film is formed in only the bevel portion on one face side of the substrate.
